(19) United States
(12) Patent Application Publication
(10) Pub. No.: US 2010/0226111 A1
(43) Pub. Date: Sep. 9, 2010

(54) TEST SWITCH COVER ASSEMBLY

(75) Inventors: Robert Goodin, Debary, FL (US); Roy Ball, Coral Springs, FL (US)

Correspondence Address: ABB INC.;LEGAL DEPARTMENT-4U6, 29801 EUCLID AVENUE, WICKLIFFE, OH, 44092, US

(73) Assignee: ABB Technology AG, Zurich (CH)

(21) Appl. No.: 12/716,091

(22) Filed: Mar. 2, 2010

Related U.S. Application Data
(60) Provisional application No. 61/157,218, filed on Mar. 4, 2009.

(51) Int. Cl. H05K 7/00

(52) U.S. Cl. 361/807

(57) ABSTRACT

A cover assembly protects a test switch having a pair of forwardly extending, opposed posts. The cover assembly includes cover having a pair of holes on opposed sides of the front face. A thumbnut is secured within each hole. Each thumbnut includes a nut having internal threads to rotatably engage the posts extending from the cover. The nut is made of a magnetic material such that, when removed, the cover assembly may be secured to any metallic surface.

This application claims priority to U.S. Provisional Application No. 61/157218 titled Test Switch Cover Assembly and filed on Mar. 4, 2009, the contents of which are incorporated by reference in their entirety.

### BACKGROUND

Protective relays are commonly used in electric utility applications to detect various possible problems in electrical power output. Such relays protect a wide variety of equipment and are used in relay systems which also include circuit breakers. The primary function of a relay is to provide trip signals to circuit breakers.

Generally, current transformers and potential transformers are employed to obtain a signal in high current and/or high potential applications. Transformers reduce the magnitude of the current or voltage, and then feeds the signal to the relays, meters and instruments at a much lower level for detection. The relay terminals may then be electrically connected to a test switch terminal or poles. Each test switch can be associated with one or more relays. As is known in the art, it is necessary to short circuit the line and load terminals when the relay is removed from its case or the adjacent test switch is opened. The test switch provides this necessary short circuit or bypass feature. If this short circuit does not occur, the associated current transformer may be damaged and the safety of nearby personnel could be jeopardized.

With reference to FIG. 1, an exemplary prior art test switch is shown and generally indicated by the numeral 10. The variety and extensive types of test switches available allows for many types of applications. As is well known to those of ordinary skill in the art these applications include but are not limited to a test switch with all potential switches, that is, no switches associated with current transformers, or all of the switches in a test switch associated with current transformers.

Test switch 10 includes on its front face 10 switches 12a to 12j arranged in five (5) sets. In the embodiment shown in FIG. 1 three (3) sets of switches, namely 12a and 12b, 12c and 12d, and 12e and 12f, are associated with a respective one of three (3) current transformers (not shown). As is well known, each current transformer is associated with a respective one of the three (3) phases of a three phase power source. Test switch 10 also includes four potential switches 12g, 12h, 12i and 12j with one of the four switches associated with phase A of the three phase source, a second of the four switches associated with phase B of the three phase source, a third of the four switches associated with phase C of the three phase source and the fourth switch associated with the neutral of the three phase power source.

An example of the three sets of switches associated with a current transformer are shown in FIG. 2. The two switches in each of the three sets of switches associated with a current transformer include a switch such as switch 12a, 12c or 12e which has a shorting blade 14 and a switch such as switch 12b, 12d or 12f which does not have a shorting blade. The switch 12a, 12c or 12e with the shorting blade provides when opened the desired short circuit of the line and and load terminals when that switch is opened. The switch 12b, 12d or 12f without the shorting blade provides a current test jack 16.

As is known in the art, test switch 10 also includes a plurality of terminals 18a-j on its rear face for connection to the relays associated with the current transformers and the three phases and neutral of the three phase source. When test switch 10 is mounted in a switchboard panel the switches 12a to 12j are accessible from the front of the panel and the rear terminals are accessible from the rear of the panel.

Prior art test switches typically include a pair of threaded posts that extend from the front face. These posts are received in holes in a cover, which fits over and protects the front face. A threaded thumbnut is then secured to the protruding posts to hold the cover in place during normal operation.

When the switch must be accessed, the cover must be removed. In the past, covers have been misplaced once removed. In other instances, the covers have been damaged after removal when placed in non-safe locations. Thus, there is a need in the art to provide a cover for a test switch which minimizes the risk of loss or damage when the cover is removed.

### SUMMARY OF THE INVENTION

According to one aspect of the present invention, a cover assembly is provided for protecting a test switch having a pair of forwardly extending, opposed posts, each post including a threaded portion. The cover assembly includes a cover including a front wall having a pair of holes on opposed sides of the front wall, the holes are sized to receive at least a portion of the posts therethrough. A pair of thumbnuts are provided, each including a hollow cylindrical body portion. A plurality of resilient tabs extend outwardly from a first end of the hollow cylindrical portion. An annular gripping portion is positioned at a second end of the hollow cylindrical portion. The annular gripping portion has a larger radius than the hollow cylindrical portion. A nut is positioned at the second end radially interior to the annular gripping portion. The nut includes a threaded hole for engaging the threaded portion of the post. Each thumbnut is positioned in one of the holes and the nut is composed of a first material and all other components of the thumbnut are composed of a second material, the first material being a metallic magnetic material.

According to another aspect of the present invention, a cover assembly is provided for protecting a test switch having a pair of forwardly extending, opposed posts. Each post includes a threaded portion. The cover assembly includes a cover including a front wall having a pair of holes on opposed sides of the front wall. The holes are sized to receive at least a portion of the posts therethrough. A thumbnut is positioned in each hole and includes a threaded hole for engaging the threaded portion of the post. A tether is secured at a first end to the cover and at a second end has a looped portion sized to removably receive the post therein. The looped portion is made of a magnetic material.

### BRIEF DESCRIPTION OF THE DRAWINGS

FIG. 1 is a side view of a prior art test switch assembly.

FIG. 2 is an isometric view of a shorting blade and a non-shorting blade type prior art test switch.

FIG. 3 is an isometric view of a test switch housing.

FIG. 4 is a side view of a test switch housing.

FIG. 5 is an isometric view of a cover assembly mounted to the test switch.

FIG. 6 is a side view of a cover assembly mounted to the test switch.

FIG. 7 is an isometric view of a thumbnut according to the present invention.

FIG. 8 is a side view of a thumbnut of FIG. 7.

FIG. 9 is a top view of the thumbnut of FIG. 7.

FIG. 10 is a side view of a cover assembly magnetically coupled to a metallic surface.

FIG. 11 is an isometric view of a cover according to a second embodiment of the present invention.

FIG. 12 is a rear view of the cover of FIG. 11.

FIG. 13 is a side view of the cover of FIG. 11 magnetically coupled to a metallic surface.

FIG. 14 is an isometric view of a cover according to a third embodiment of the present invention.

FIG. 15 is a rear view of the cover of FIG. 14.

FIG. 16 is an isometric view of a test switch according to the third embodiment of the present invention.

FIG. 17 is a side view of the test switch of FIG. 16.

FIG. 18 is a side view of the cover of FIG. 14 magnetically coupled to a metallic surface.

FIG. 19 is an isometric view of a test switch and cover according to a fourth embodiment.

FIG. 20 is an alternate isometric view of the test switch and cover of FIG. 19.

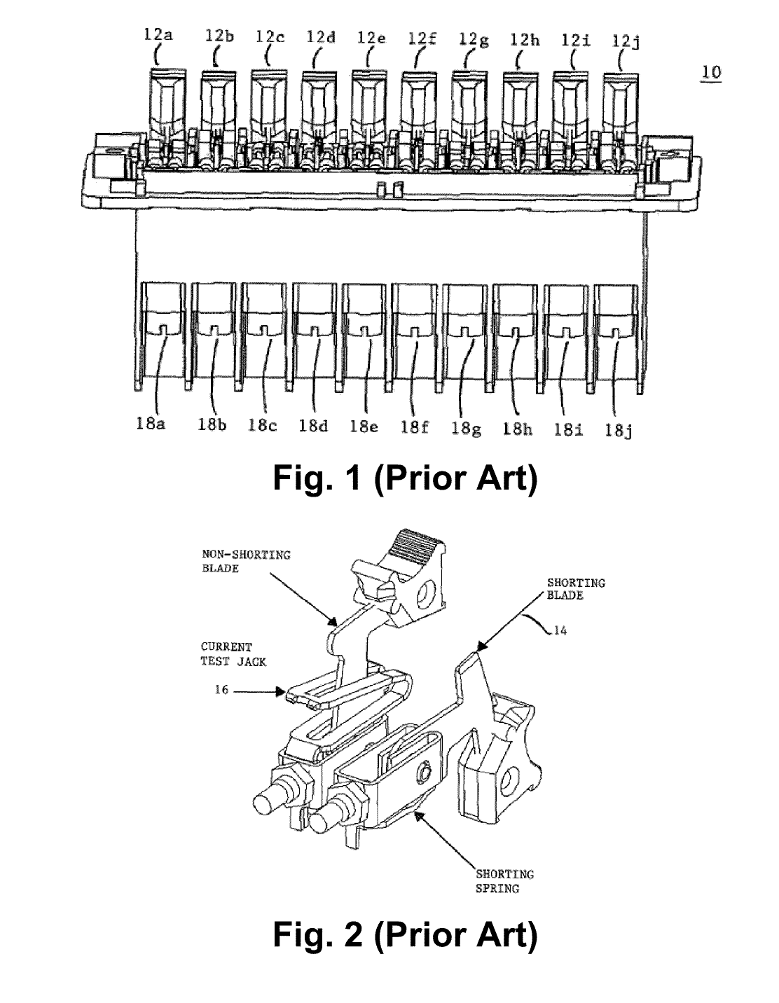

### DETAILED DESCRIPTION OF THE INVENTION

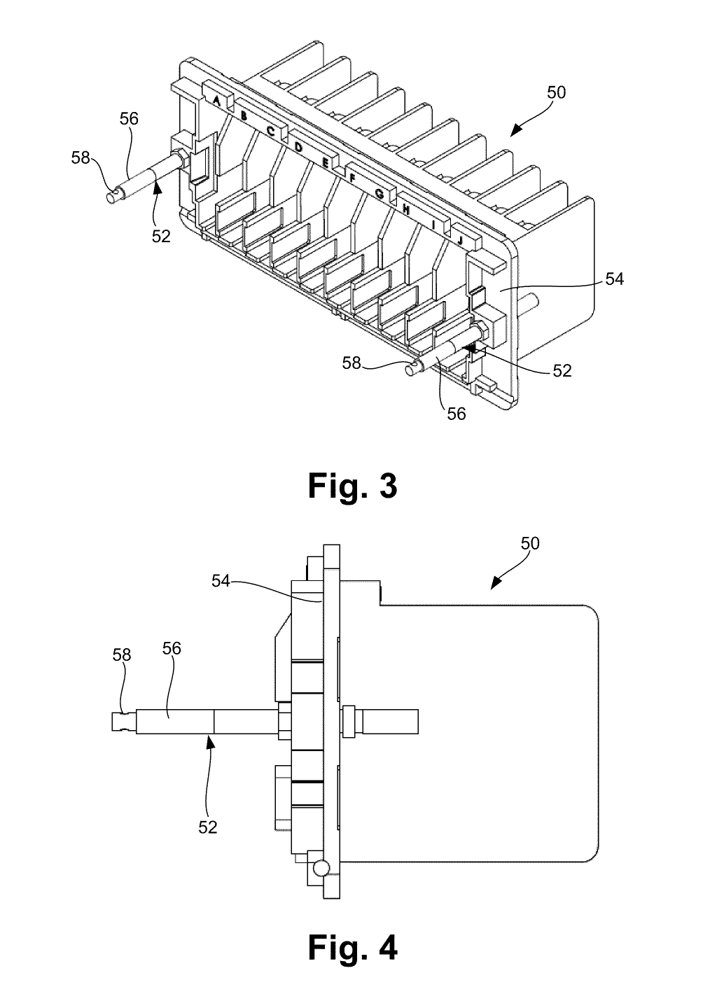

With reference now to FIGS. 3 and 4, a test switch 50 is shown with the individual switches removed for clarity. Test switch 50 includes a pair of mounting posts 52 that extend forwardly from the front surface 54 of test switch 50. Each post 52 includes a threaded area 56. Each post 52 further includes a hole 58 proximate to the end thereof.

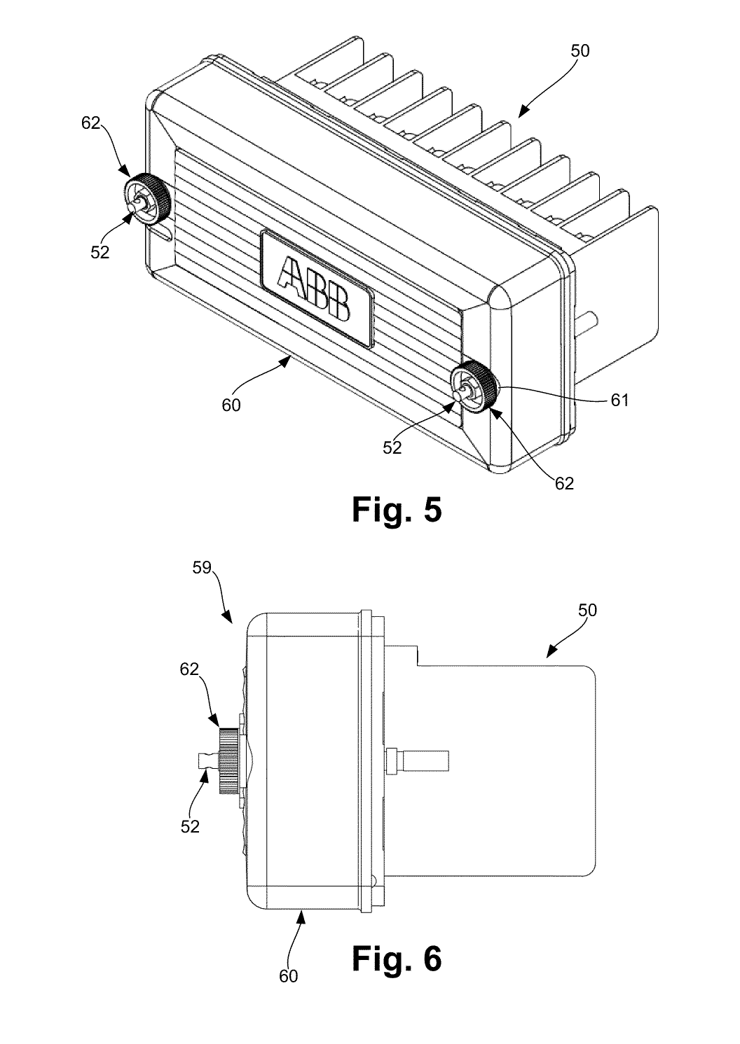

With reference now to FIGS. 5 and 6, a cover assembly 59 may be positioned over the front surface of test switch 50. Cover assembly 59 includes a cover 60 having a pair of holes 61 through which at least a portion of the threaded area 56 extends. A thumbnut 62 is rotatively received by threaded portion 56 and, in a twisting manner, may be tightened, so that cover 60 is held firmly against test switch 50. After cover 50 is adequately tightened against test switch 50, a retaining clip (not shown) may be inserted into holes 58 to prevent cover 60 from being removed.

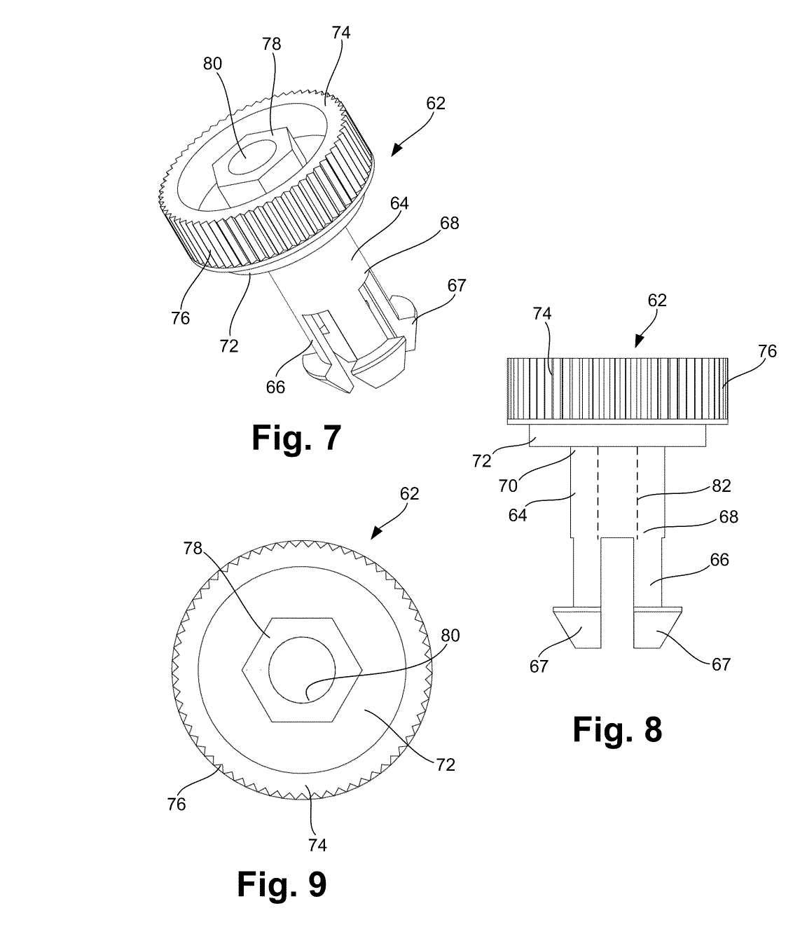

With reference now to FIGS. 7-9, thumbnut 62 is shown in greater detail. As can be seen, thumbnut 62 includes a hollow cylindrical central body portion 64. A plurality of axially extending, circumferentially spaced tabs 66 extend from a first end 68 of central body portion 64. Tabs 66 include radially extending fingers 67 and may be flexible and resilient so that they may be depressed radially inwardly during insertion into the hole 61 in cover 60. However, once inserted, tabs 66 recover their original configuration and thereafter prevent removal of thumbnut 62 from cover 60.

At the second end 70 of body portion 64 a flange 72 extends radially outwardly. An annular gripping portion 74 extends from the outer edge of flange 72. As can be seen, annular gripping portion 74 includes a radially facing grip surface 76 that includes a plurality of ridges that improves a human's grip of thumbnut 62.

Thumbnut 62 includes a nut 78 having a central threaded hole 80 that is axially aligned with the hollow center 82 central body portion 64. The hollow center 82 of body portion 64 includes a radius that is equal to or larger than the radius of threaded hole 80. According to one embodiment, nut 78 may be in the form of a hex nut.

At least some portion of thumbnut 62 is made of a magnetic material.

According to one particularly advantageous embodiment, nut 78 is formed of a magnetic metallic material and the remaining parts of thumbnut 62 may be formed of a non-magnetic material. According to this embodiment, a magnetized nut 78 may be provided, and the remaining parts of thumbnut 62 may be formed of a plastic material, over-molded over nut 78.

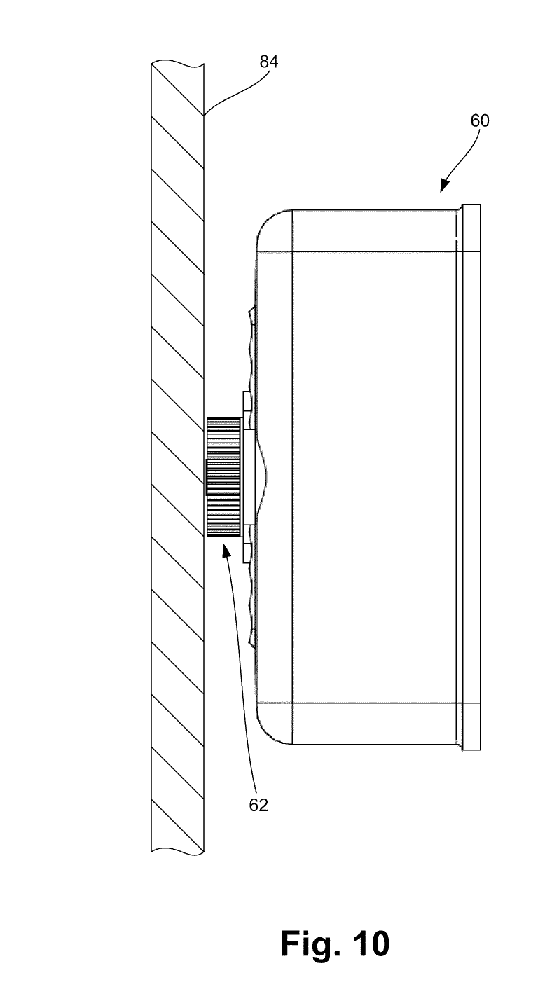

With reference now to FIG. 10, the use of cover assembly 59 will be described in greater detail. When cover 60 is removed from test switch 50, tabs 66 prevent thumbnut 62 from completely detaching from cover 60. In this configuration, the thumbnuts 62 may be placed against any generally flat, metallic surface 84. The outwards facing surface of nut 78 extends even with or slightly further than the gripping portion 74 and thus, nut 78 contacts the metallic surface 84 and magnetically retains the thumbnut 62 against the metallic surface. In this manner, the cover assembly 59 is retained proximate to the metallic surface. This prevents covers from being damaged or lost, as the cover may be secured to any metallic object nearby. In fact, the test switches are typically installed in a metal cabinet, and thus, the cover assembly 59 may be secured directly to the cabinet, proximate to the switch.

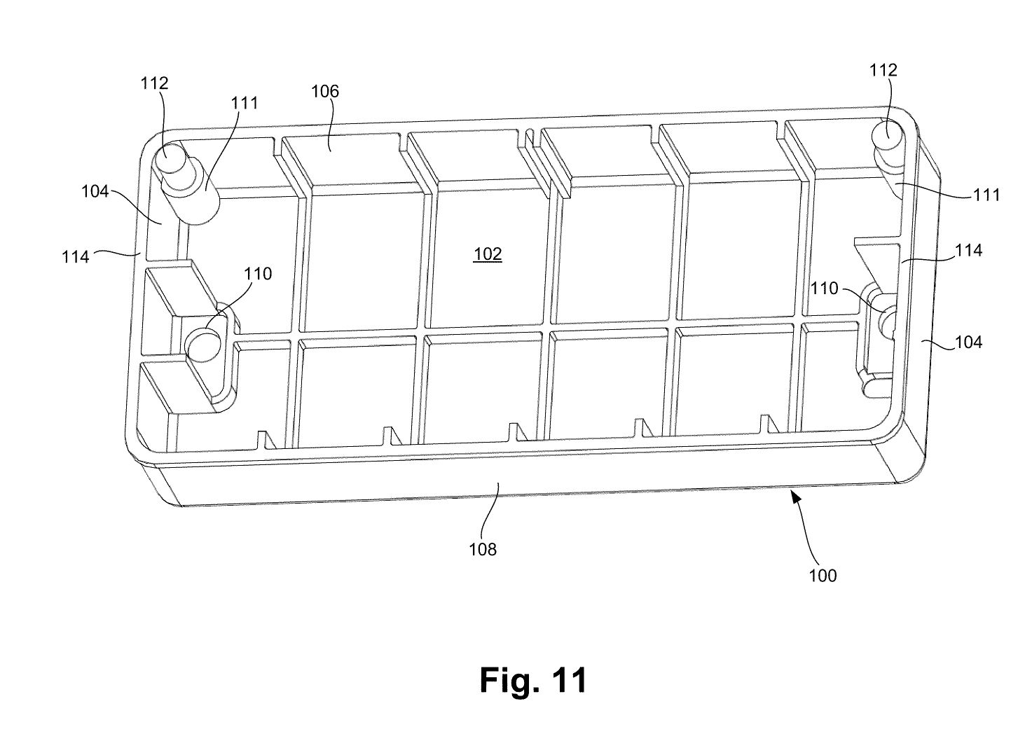

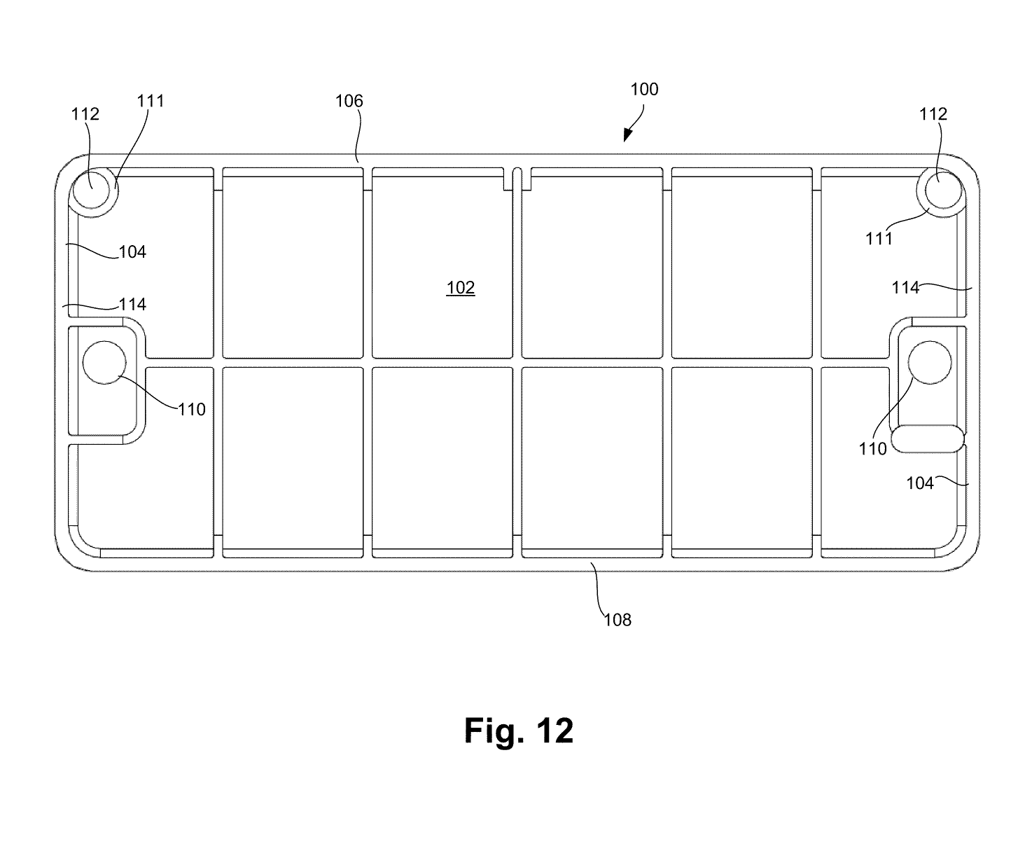

With reference now to FIGS. 11-13, a second embodiment of the present invention is disclosed. A cover 100 includes the same general features and structure as cover 60 disclosed above. Accordingly, cover 100 includes a generally rectangular, open body having a front wall 102, a pair of opposed side walls 104, a top wall 106 and a bottom wall 108. Likewise, a pair of holes 110 are provided at opposed ends of front wall 102. A pair of projections extend rearward from front wall 102 proximate to the intersections of top wall 106 and side walls 104. A magnet 112 is secured to each projection 111 and extends to a location approximately flush with the rear peripheral edge 114 of side walls 104.

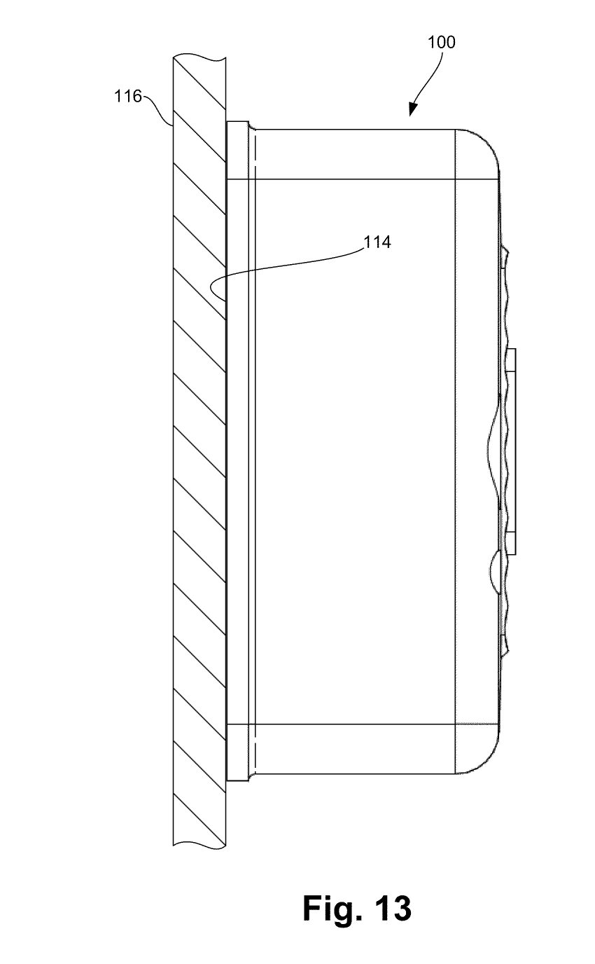

During normal use, cover 100 is secured to test switch 50 in the same manner as discussed above, wherein a thumbnut is secured to a post that extends through hole 110. When cover 100 is removed from a test switch, the rear edge 114 may be positioned proximate to a generally flat, metallic surface 116 so that magnets 112 hold cover 100 thereto. According to this embodiment, thumbnuts may be removed (as shown in FIG. 13) or may remain secured within holes 110. In this manner, the cover 100 is retained proximate to the metallic surface during use of the test switch.

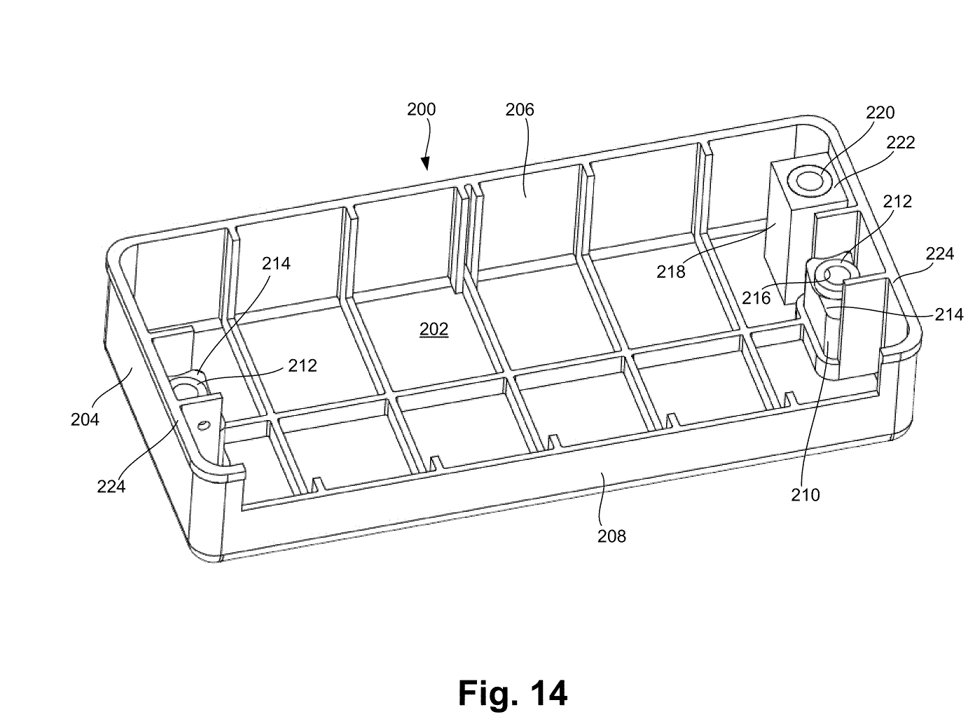

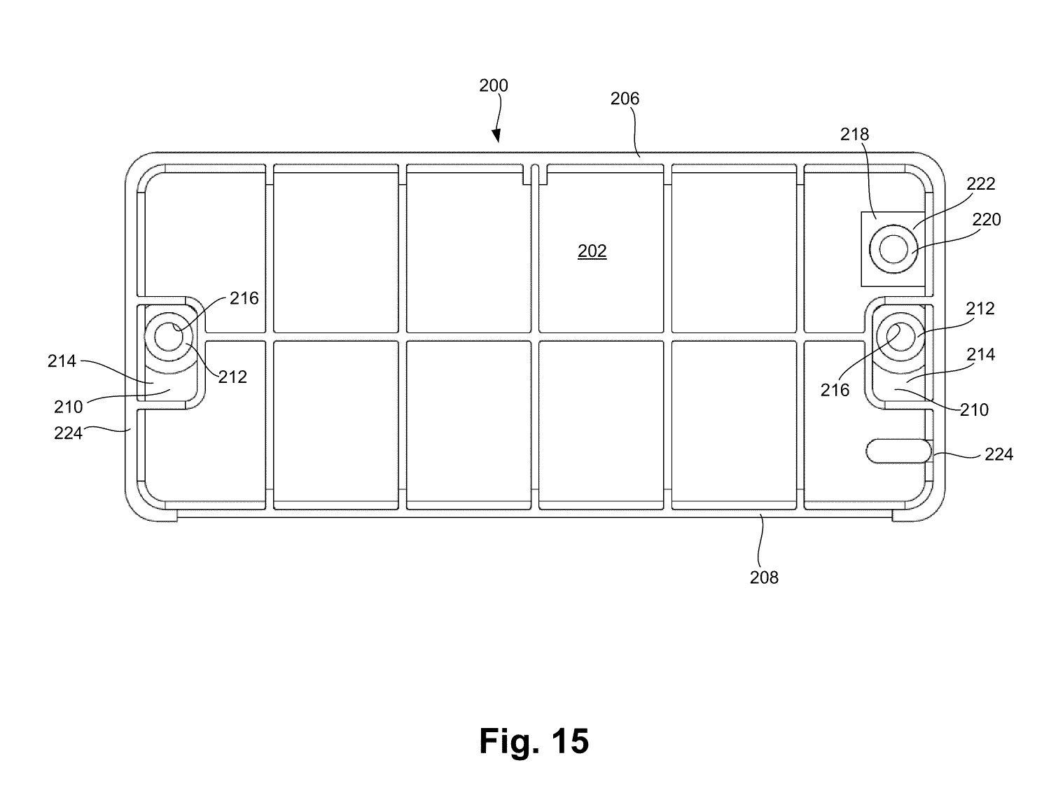

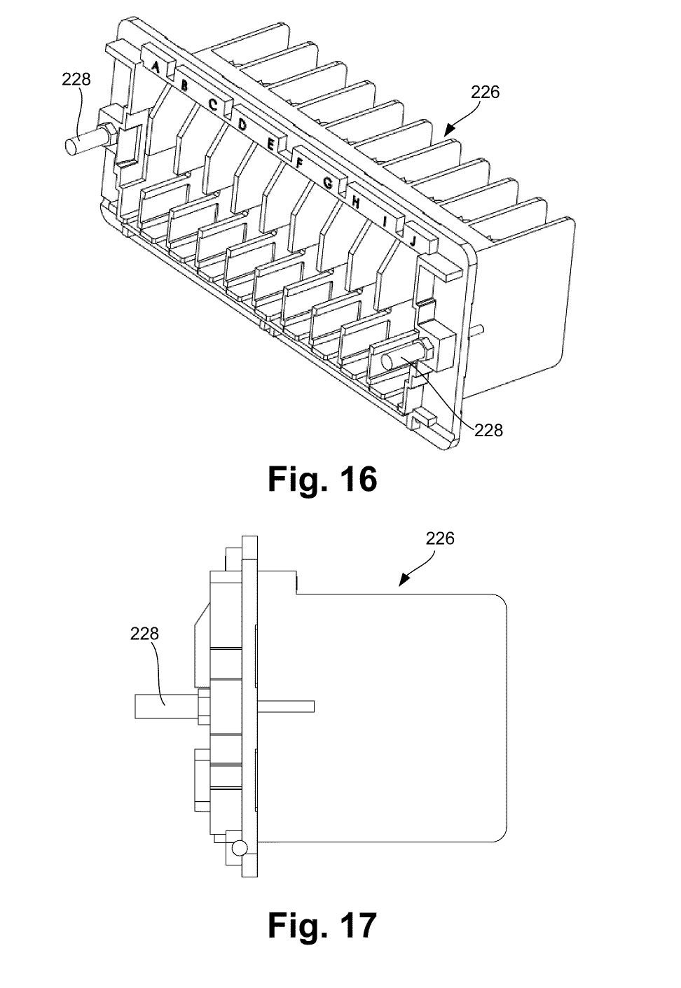

With reference now to FIGS. 14-17, a third embodiment of the present invention is disclosed. A cover 200 includes the same general features and structure as cover 60 and 100 disclosed above. Accordingly, cover 200 includes an open, generally rectangular body having a front wall 202, a pair of opposed side walls 204, a top wall 206 and a bottom wall 208. However, as will be discussed in further detail below, cover 200 does not include holes on front wall 202.

Cover 200 includes a pair of projections 210 that extend rearwardly from front wall 202. One projection 210 is proximate to each side wall 204 so that projections 210 are on opposed ends of cover 200. Projections 210 extend rearwardly about half the depth of side wall 204. Each projection 210 carries a magnet 212 on its rear face 214. Ring shaped magnet 212 is cylindrical or ring shape and defines a central aperture 216.

Cover 200 includes an additional projection 218 that extends rearwardly from front wall 202. Projection 218 is positioned proximate to one of side walls 204 between projection 210 and top wall 206. Projection 218 extends rearwardly nearly the same depth as side wall 204. Projection 218 carries a magnet 220 on its rear face 222. Magnet 220 may extend rearwardly from rear surface 222 so that it is even with or extends slightly past the rear edge 224 of side wall 204.

Cover 200 protects a test switch 226 that is substantially identical to the test switch 50 described above with the exception that posts 228 are modified. Posts 228 do not include a threaded area and are sized to be received in central apertures 216. According to one embodiment, posts 226 are metallic and thus, by inserting posts 228 into apertures 216, cover 200 is retained against test switch 226. According to another embodiment, posts 228 may also be magnetic, thus facilitating an even stronger attraction between cover 200 and test switch 226.

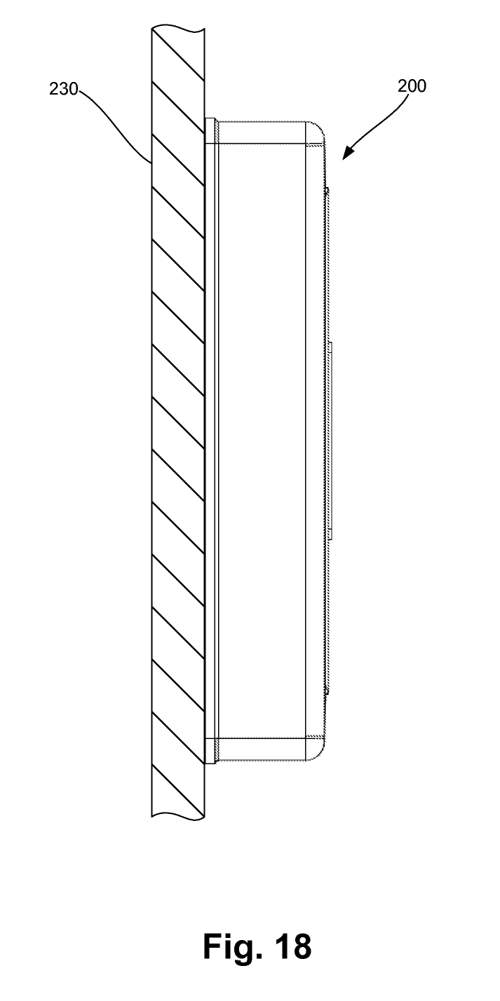

Should a maintenance person wish to access test switch 226, cover 200 is pulled forward with sufficient force to break the magnetic bonds between magnets 212 and posts 228. Thereafter, the cover 200 may be positioned proximate to a generally flat, metallic surface 230 such that magnet 220 holds cover 200 thereto (see FIG. 18). In this manner, the cover 200 is retained proximate to the metallic surface 230 until such time that the cover 200 is reattached to test switch 226.

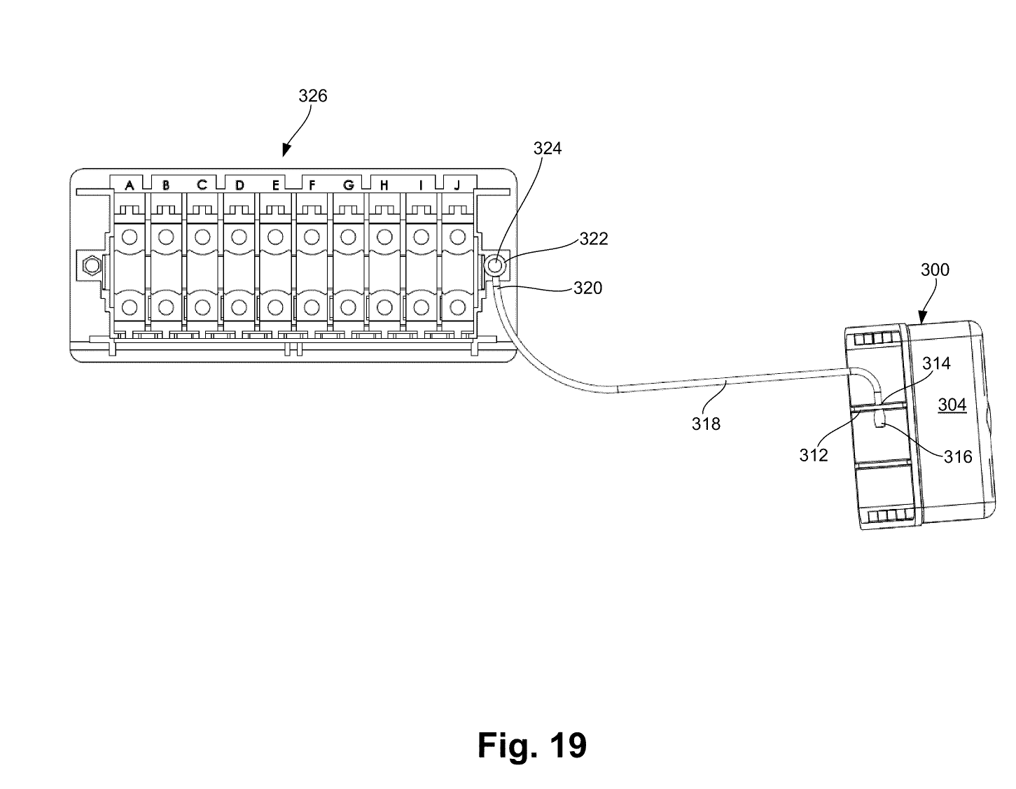

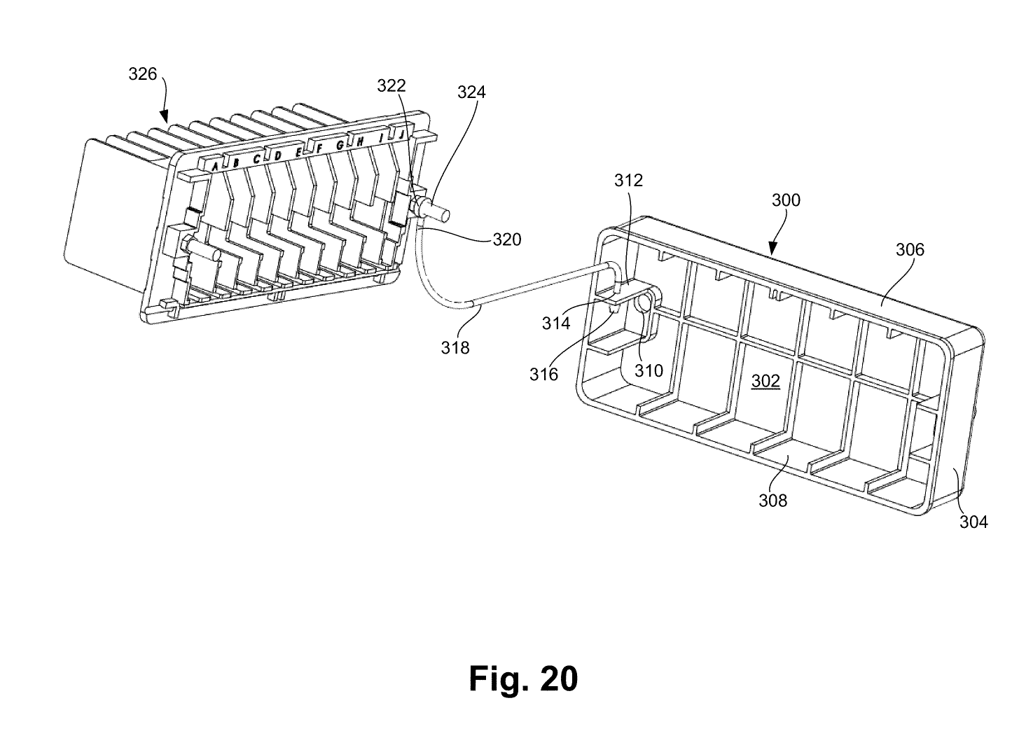

With reference now to FIGS. 19 and 20, a fourth embodiment is disclosed. Cover 300 includes the same general features and structure as covers 60, 100, and 200 disclosed above. Accordingly, cover 300 includes an open, generally rectangular body having a front wall 302, a pair of opposed side walls 304, a top wall 306 and a bottom wall 308. A pair of holes 310 are provided at opposed ends of front wall 302. At least one rib 312 is positioned proximate to one of holes 310 and extends rearwardly from front wall 302 approximately the depth of side wall 304. Rib 312 includes a hole 314 through which a first end 316 of a tether 318 is inserted and secured. Tether 318 is a flexible cord, cable, rope, or the like. The second end 320 of tether 318 includes a looped or annular portion 322. Looped portion 322 is received around post 324 of test switch 326.

During normal use, cover 300 is secured to test switch 326 in the same manner as discussed above, wherein a thumbnut is secured to a post 324 extending through holes 310. When cover 300 is removed from test switch 326, the tether 318 holds cover 300 beneath test switch 326. In this manner, the cover 300 is retained near the test switch 326. This prevents the cover from being damaged or lost.

According to yet another embodiment, the looped portion 322 may be made of a magnetic material. This magnetic material may help hold the looped portion 322 on post 324. Further, tether 318 may be removed from post 324, and looped portion 322 may be placed against any metallic surface. Thereafter, the magnetic attraction holds loop portion, and consequently cover 300, until such time that the cover is reaffixed to test switch 326.

It is to be understood that the description of the foregoing exemplary embodiment(s) is (are) intended to be only illustrative, rather than exhaustive, of the present invention. Those of ordinary skill will be able to make certain additions, deletions, and/or modifications to the embodiment(s) of the disclosed subject matter without departing from the spirit of the invention or its scope, as defined by the appended claims.

What is claimed is:

1. A cover assembly for protecting a test switch having a plurality of switches and a pair of forwardly extending posts, positioned on opposed sides of the plurality of switches, each said post including a threaded portion, said cover assembly comprising:
a cover sized to encapsulate the plurality of switches and including a front wall having a pair of holes on opposed sides of said front wall, said holes sized to receive at least a portion of the posts therethrough;
a pair of thumbnuts each including a hollow cylindrical body portion, a plurality of resilient tabs extending outwardly from a first end of said hollow cylindrical portion, an annular gripping portion positioned at a second end of said hollow cylindrical portion, said annular gripping portion having a larger radius than said hollow cylindrical portion, and a nut positioned at said second end radially interior to said annular gripping portion, said nut including a threaded hole for engaging the threaded portion of the post, and
wherein each said thumbnut is positioned in one of said holes and said nut is composed of a first material and all other components of said thumbnut are composed of a second material, said first material being a metallic magnetic material.

2. The cover of claim 1 wherein said gripping portion includes a radially facing surface, said radially facing surface including a plurality of ridges.

3. The cover of claim 1 wherein said second material is a plastic material.

4. The cover of claim 1 wherein each said tab includes a radially extending finger for engaging said front wall of said cover.

5. The cover of claim 1 wherein said nut and said gripping portion include an outer surface that is co-planar.

6. A cover assembly for protecting a test switch having a pair of forwardly extending opposed posts, each said post including a threaded portion, said cover assembly comprising:
a cover including a front wall having a pair of holes on opposed sides of said front wall, said holes sized to receive at least a portion of the posts therethrough;
a thumbnut positioned in each hole and including a threaded hole for engaging the threaded portion of the post, and
a tether, secured at a first end to said cover and at a second end having a looped portion sized to removably receive the post therein, said looped portion being composed of a magnetic material.

7. The cover of claim 6 wherein said tether is a flexible cord.

8. The cover of claim 6 wherein cover includes an internal rib having a hole, said first end of said tether being received in said hole.
